(19) United States
(12) Patent Application Publication
(10) Pub. No.: US 2012/0211862 A1
(43) Pub. Date: Aug. 23, 2012

(54) SOI SUBSTRATE AND METHOD FOR MANUFACTURING SOI SUBSTRATE

(75) Inventors: Masaharu NAGAI, Atsugi (JP); Hideto OHNUMA, Atsugi (JP); Kosei NEI, Atsugi (JP)

(73) Assignee: SEMICONDUCTOR ENERGY LABORATORY CO., LTD., Atsugi-shi (JP)

(21) Appl. No.: 13/372,541

(22) Filed: Feb. 14, 2012

(30) Foreign Application Priority Data
Feb. 18, 2011 (JP) 2011-033698

(51) Int. Cl. H01L 29/06; H01L 21/762; H01L 21/302

(52) U.S. Cl. 257/506; 438/694; 438/479; 257/E21.214; 257/E21.561; 257/E29.02

(57) ABSTRACT

The method for manufacturing an SOI substrate includes the following steps: forming an insulating film on a semiconductor substrate; exposing the semiconductor substrate to accelerated ions so that an embrittlement region is formed in the semiconductor substrate; bonding the semiconductor substrate to a base substrate with the insulating film interposed therebetween; separating the semiconductor substrate along the embrittlement region so that a semiconductor film is provided over the base substrate with the insulating film interposed therebetween; and forming a mask over the semiconductor film to etch part of the semiconductor film and part of the insulating film so that the periphery of the semiconductor film is on the inner side than the periphery of the insulating film.

### BACKGROUND OF THE INVENTION

1. Field of the Invention

The present invention relates to a method for manufacturing a so-called silicon-on-insulator (SOI) substrate in which a semiconductor film is provided over a base substrate with an insulating film interposed therebetween.

2. Description of the Related Art

In recent years, integrated circuits formed using an SOI substrate in which a thin silicon film is provided on its insulating surface, instead of a silicon substrate, have been developed. SOI substrates have attracted attention as the substrates which can improve the performance of semiconductor integrated circuits because they are superior to silicon substrates in point of ease of dielectric isolation which is advantageous in high integration, small stray capacitance which allows high-speed operation of elements, and the like.

One of known methods for manufacturing SOI substrates is a Smart Cut (registered trademark) method. A summary of a method for manufacturing an SOI substrate by a Smart Cut method will be described below. First, hydrogen ions are implanted into a silicon substrate by an ion implantation method to form a microbubble layer in the silicon substrate. Then, the silicon substrate in which the microbubble layer is formed is bonded to another silicon substrate with a silicon oxide film interposed therebetween. After that, the silicon substrate is separated along the microbubble layer through heat treatment, so that a single crystal silicon film can be provided over the another silicon substrate. Note that a Smart Cut method may be referred to as a hydrogen ion implantation separation method.

Further, a method for providing a single crystal silicon film over a base substrate other than a silicon substrate (e.g., a glass substrate) by such a Smart Cut method has been proposed (e.g., see Patent Document 1). Glass substrates are also used in manufacturing liquid crystal display devices and the like because they can have larger areas and are less expensive than silicon substrates.

### REFERENCE

[Patent Document 1] Japanese Published Patent Application No. 2005-252244

### SUMMARY OF THE INVENTION

There is a problem that part of a single crystal silicon film might peel off a base substrate in a portion where the bonding strength between the single crystal silicon film and the base substrate is low (particularly on the periphery of the single crystal silicon film) in the case where a substrate other than a silicon substrate, such as a glass substrate, is used as the base substrate. This is because the bonding strength of the periphery of the single crystal silicon film provided over the base substrate with an insulating film interposed therebetween is low and thus in a cleaning step or wet etching treatment, a chemical solution enters a gap between the single crystal silicon film and the base substrate (which is also between the insulating film and the base substrate), resulting in etching of the base substrate. Peeling of even part of the single crystal silicon film from the base substrate finally causes a problem of peeling of the whole single silicon film from the base substrate.

When part or the whole of the single crystal silicon film peels off the base substrate as described above, there occurs a problem that the yield decreases and the manufacturing cost increases in manufacture of SOI substrates.

In view of the above problems, an object of one embodiment of the present invention is to provide a method for preventing a semiconductor film such as a single crystal silicon film from peeling off a base substrate. Another object is to increase the yield and reduce the manufacturing cost with the above method.

Provided in one embodiment of the present invention is a method for providing a semiconductor film over a base substrate so that the periphery of the semiconductor film is on the inner side than the periphery of an insulating film. Specific description thereof will be given below. Note that a “periphery” in this specification and the like refers to an end portion of a film or the like when the film or the like is seen from above the top surface thereof.

According to one embodiment of the present invention, a method for manufacturing an SOI substrate includes the following steps: forming an insulating film on a semiconductor substrate; exposing the semiconductor substrate to accelerated ions through the insulating film so that an embrittlement region is formed in the semiconductor substrate; bonding the semiconductor substrate to a base substrate with the insulating film interposed therebetween; separating the semiconductor substrate along the embrittlement region so that a semiconductor film is provided over the base substrate with the insulating film interposed therebetween; and forming a mask over the semiconductor film to etch the periphery of the semiconductor film and part of the insulating film so that the periphery of the semiconductor film is on the inner side than the periphery of the insulating film.

According to one embodiment of the present invention, a method for manufacturing an SOI substrate includes the following steps: forming an insulating film on a semiconductor substrate; exposing the semiconductor substrate to accelerated ions through the insulating film so that an embrittlement region is formed in the semiconductor substrate; bonding the semiconductor substrate to a base substrate with the insulating film interposed therebetween; separating the semiconductor substrate along the embrittlement region so that a semiconductor film is provided over the base substrate with the insulating film interposed therebetween; and performing atmospheric pressure plasma etching on the periphery of the semiconductor film and part of the insulating film so that the periphery of the semiconductor film is on the inner side than the periphery of the insulating film.

In each of the above methods, the etching is preferably performed so that the taper angle of the insulating film is larger than or equal to 3° and smaller than or equal to 60°, more preferably larger than or equal to 3° and smaller than or equal to 45°. When the etching is thus performed, it is possible to prevent removal of part of the base substrate between the insulating film and the base substrate due to a difference between the etching rate of the insulating film and the etching rate of the base substrate in a cleaning step or wet etching treatment. Consequently, part or the whole of the semiconductor film can be prevented from peeling off the base substrate.

Note that in each of the above methods, the taper angle of the periphery of the semiconductor film may be larger than or equal to 30° and smaller than or equal to 90°.

Note that in each of the above methods, after the periphery of the semiconductor film and part of the insulating film are removed so that the periphery of the semiconductor film is on the inner side than the periphery of the insulating film, the semiconductor film is preferably irradiated with laser light. Laser light irradiation of the semiconductor film enables planarization of a surface of the semiconductor film. Further, the semiconductor film can be recrystallized; thus, the crystallinity of the semiconductor film can be improved.

According to one embodiment of the present invention, etching is performed so that the taper angle of the periphery of the insulating film is larger than or equal to 3° and smaller than or equal to 60°, preferably larger than or equal to 3° and smaller than or equal to 45°. Accordingly, it is possible to suppress side etching due to a difference between the etching rate of the insulating film and the etching rate of the base substrate when an insulating film formed on a surface of the semiconductor film is removed in a cleaning step before laser light irradiation; thus, removal of part of the base substrate at the interface between the insulating film and the base substrate can be suppressed. Consequently, the insulating film formed on the surface of the semiconductor film can be removed while part or the whole of the semiconductor film can be prevented from peeling off the base substrate.

One embodiment of the present invention is an SOI substrate including a base substrate, an insulating film on the base substrate, and a semiconductor film on the insulating film. The insulating film and the semiconductor film each have compressive stress. Compressive stress of the insulating film is higher than that of the semiconductor film. The periphery of the semiconductor film is on the inner side than the periphery of the insulating film.

According to one embodiment of the present invention, the semiconductor film such as a single crystal silicon film can be prevented from peeling off the base substrate. Moreover, any of the above methods makes it possible to increase the yield and reduce the manufacturing cost.

### BRIEF DESCRIPTION OF THE DRAWINGS

In the accompanying drawings:

FIGS. 1A1 to 1D illustrate a method for manufacturing an SOI substrate, according to one embodiment of the present invention;

FIGS. 2A to 2E illustrate a method for manufacturing an SOI substrate, according to one embodiment of the present invention;

FIGS. 3A and 3B illustrate methods for manufacturing an SOI substrate, according to one embodiment of the present invention;

FIG. 4 illustrates an SOI substrate according to one embodiment of the present invention;

FIGS. 5A to 5C illustrate a method for manufacturing an SOI substrate, according to one embodiment of the present invention;

FIGS. 6A to 6E illustrate a method for manufacturing an SOI substrate, according to one embodiment of the present invention;

FIGS. 7A and 7B are views for explaining stresses of a semiconductor film and an oxide film on a base substrate;

FIGS. 8A and 8B are views for explaining stresses of a semiconductor film and an oxide film on a base substrate;

FIGS. 9A and 9B illustrate a semiconductor device including an SOI substrate according to one embodiment of the present invention;

FIGS. 10A to 10F each illustrate an electronic device including an SOI substrate according to one embodiment of the present invention;

FIG. 11 is a SEM image of Sample A;

FIGS. 12A and 12B are SEM images of Sample B and Sample C, respectively;

FIG. 13 is a STEM image of Sample D;

FIG. 14 is a STEM image of Sample E; and

FIG. 15 shows measurement results of stresses of a semiconductor film and an oxide film.

### DETAILED DESCRIPTION OF THE INVENTION

Hereinafter, embodiments and examples of the present invention will be described in detail with reference to the accompanying drawings. Note that the present invention is not limited to the description below, and it is easily understood by those skilled in the art that modes and details of the present invention can be modified in various ways without departing from the spirit and the scope of the present invention. Therefore, the present invention is not construed as being limited to description of the embodiments and the examples.

### Embodiment 1

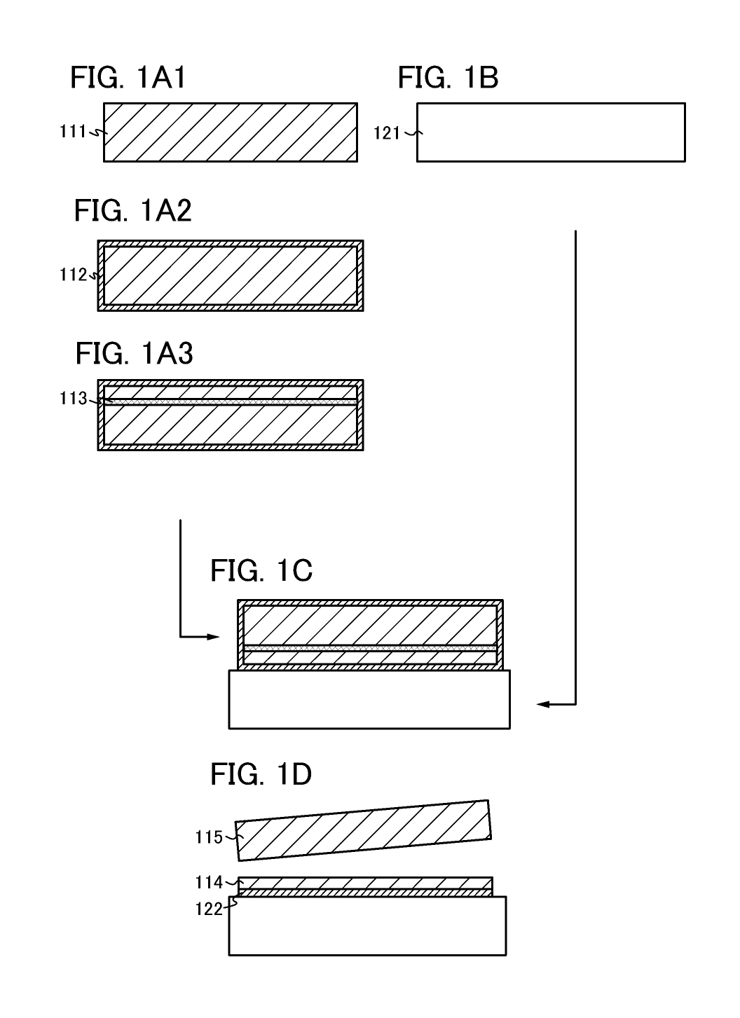

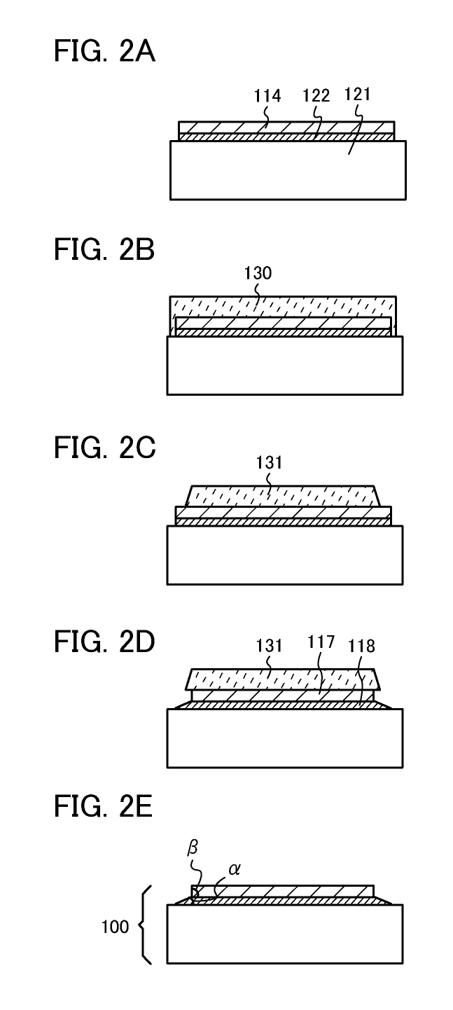

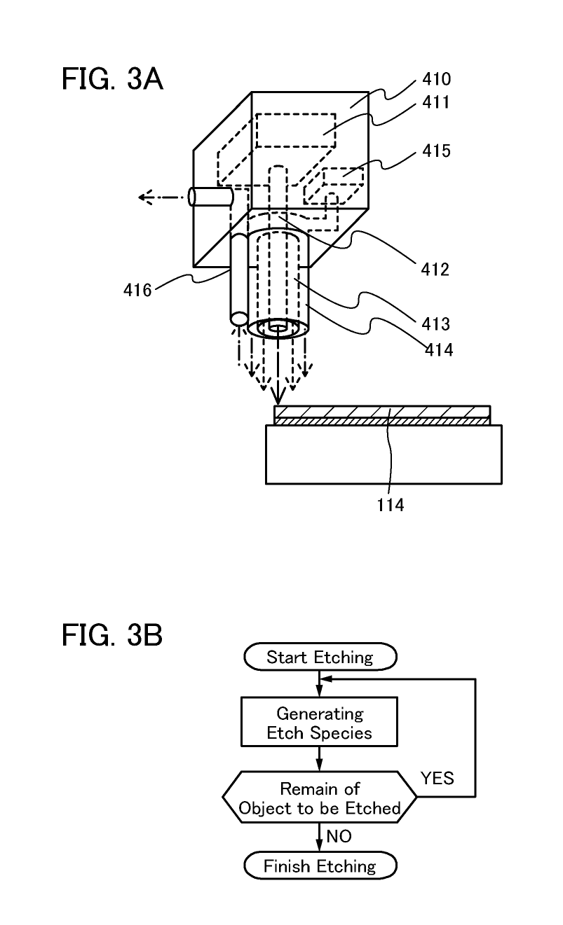

In this embodiment, a method for manufacturing an SOI substrate according to one embodiment of the present invention will be described with reference to FIGS. 1A1 to 1D, FIGS. 2A to 2E, and FIGS. 3A and 3B.

First, a semiconductor substrate 111 is prepared (see FIG. 1A1).

As the semiconductor substrate 111, a single crystal semiconductor substrate or a polycrystalline semiconductor substrate can be used. As the semiconductor substrate 111, for example, a semiconductor substrate formed using an element belonging to Group 14 of the periodic table, such as a silicon substrate, a germanium substrate, a silicon germanium substrate, or a silicon carbide substrate, can be used. Alternatively, a compound semiconductor substrate such as a gallium arsenide substrate or an indium phosphide substrate may be used. In this embodiment, the case will be described in which a silicon substrate is used as the semiconductor substrate 111.

Next, an insulating film 112 is formed on the semiconductor substrate 111 (see FIG. 1A2).

The insulating film 112 can be formed by a CVD method, a sputtering method, a thermal oxidation treatment method, or the like. As the insulating film 112, a single layer or a stack of any of a silicon oxide film, a silicon oxynitride film, a silicon nitride oxide film, a silicon nitride film, and the like can be used. For example, in the case where the insulating film 112 is formed by a CVD method, a silicon oxide film formed using organosilane such as tetraethoxysilane (abbreviation: TEOS, chemical formula: Si(OC₂H₅)₄) is preferably used as the insulating film 112 in terms of productivity. The thickness of the insulating film 112 is greater than or equal to 10 nm and less than or equal to 1000 nm, preferably greater than or equal to 50 nm and less than or equal to 200 nm.

In this embodiment, thermal oxidation treatment is performed on a single crystal silicon substrate in an oxidative atmosphere to which halogen is added, whereby a silicon oxide film is formed. For example, the thermal oxidation treatment is preferably performed in an oxygen atmosphere containing hydrogen chloride (HCl) at more than or equal to 0.5 vol. % (preferably, 3 vol. %) at a temperature in the range of 900° C. to 1150° C. (e.g., 950° C.). Processing time may be 0.1 hours to 6 hours, preferably 0.5 hours to 1 hour. In this embodiment, the thickness of the silicon oxide film formed on the single crystal silicon substrate is 100 nm Note that the insulating film 112 includes chlorine atoms.

Next, the semiconductor substrate 111 is exposed to ions through the insulating film 112 to add the ions into the semiconductor substrate 111 so that an embrittlement region 113 is formed in the semiconductor substrate 111 (see FIG. 1A3). For example, the semiconductor substrate 111 is exposed to an ion beam including ions accelerated by an electric field, whereby the embrittlement region 113 is formed at a predetermined depth from a surface of the semiconductor substrate 111. The depth at which the embrittlement region 113 is formed can be controlled by the accelerating energy of the ion beam and the incident angle thereof. Specifically, the embrittlement region 113 is formed in a region at a depth the same or substantially the same as the average penetration depth of the ions. Here, the depth at which the embrittlement region 113 is formed is preferably uniform over the entire area of the semiconductor substrate 111.

Depending on the depth at which the embrittlement region 113 is formed, the thickness of a semiconductor film which is separated from the semiconductor substrate 111 is determined. The embrittlement region 113 is formed at a depth in the range of 50 nm to 1 μm, preferably in the range of 50 nm to 300 nm from a surface of the semiconductor substrate 111. In this embodiment, the embrittlement region 113 is formed at a depth in the range of 130 nm to 145 nm.

In order to add ions into the semiconductor substrate 111, an ion implantation apparatus or an ion doping apparatus can be used. In an ion implantation apparatus, a source gas is excited to generate ion species, the generated ion species are mass-separated, and an object to be processed is exposed to the ion species having predetermined mass. In an ion doping apparatus, a source gas is excited to generate ion species, and an object to be processed is exposed to the ion species without mass-separating the generated ion species. Note that in an ion doping apparatus provided with a mass separator, ion exposure with mass separation can also be performed as in the ion implantation apparatus.

When an ion doping apparatus is used, the embrittlement region 113 can be formed under the following conditions: the accelerating voltage is higher than or equal to 10 kV and lower than or equal to 100 kV (preferably higher than or equal to 30 kV and lower than or equal to 80 kV); the dose is greater than or equal to 1×10¹⁶ ions/cm² and less than or equal to 9×10¹⁶ ions/cm²; and the beam current density is higher than or equal to 2 μA/cm² (preferably higher than or equal to 5 μA/cm², more preferably higher than or equal to 10 μA/cm²).

In the case of using an ion doping apparatus, a gas containing hydrogen can be used as a source gas. With the gas containing hydrogen, H⁺ ions, H₂⁺ ions, and H₃⁺ ions can be produced as ion species. In the case where a hydrogen gas is used as a source gas, it is preferable to perform exposure to a larger number of H₃⁺ ions. Specifically, the proportion of H₃⁺ ions which are included in the ion beam is preferably higher than or equal to 70% with respect to the total amount of H⁺ ions, H₂⁺ ions, and H₃⁺ ions. It is more preferable that the proportion of H₃⁺ ions be higher than or equal to 80%. Such higher proportion of H₃⁺ ions allows the hydrogen concentration in the embrittlement region 113 to be 1×10²⁰ atoms/cm³ or more. Accordingly, separation along the embrittlement region 113 can be easily performed. Furthermore, with the exposure to a large number of H₃⁺ ions, the embrittlement region 113 can be formed in a shorter period of time as compared with the case of exposure to H⁺ ions and/or H₂⁺ ions. Moreover, the use of H₃⁺ ions leads to reduction in average penetration depth of ions; thus, the embrittlement region 113 can be formed in a shallow region of the semiconductor substrate.

In the case of using an ion implantation apparatus, it is preferable to perform mass separation for exposure to H₃⁺ ions. It is needless to say that exposure to H⁺ ions and H₂⁺ ions may be performed. Note that since ion species are selected in performing exposure in the case of using an ion implantation apparatus, ion irradiation efficiency is decreased as compared to the case of using an ion doping apparatus, in some cases.

As a source gas, other than a gas containing hydrogen, one or more kinds of gases selected from rare gases such as helium and argon, halogen gases typified by a fluorine gas and a chlorine gas, and a halogen compound gas such as a fluorine compound gas (e.g., BF₃) can be used. When helium is used as a source gas, an ion beam with high proportion of He ions can be formed without mass separation. The use of such an ion beam enables efficient formation of the embrittlement region 113.

Further, ion exposure may be performed plural times to form the embrittlement region 113. In this case, either different source gases or the same source gas may be used for ion exposure. For example, ion exposure can be performed using a gas containing hydrogen as a source gas after ion exposure is performed using a rare gas as a source gas. Alternatively, after ion exposure using a halogen gas or a halogen compound gas, ion exposure may be performed using a gas containing hydrogen.

Next, a base substrate 121 is prepared (see FIG. 1B). As the base substrate 121, a light-transmitting glass substrate used for a liquid crystal display device or the like can be used. As the glass substrate, the one whose strain point is 600° C. or more is preferably used. It is preferable that the glass substrate be a non-alkali glass substrate. For a non-alkali glass substrate, for example, a glass material such as aluminosilicate glass, aluminoborosilicate glass, or barium borosilicate glass is used. When a glass substrate which can have a large area and is inexpensive is used as the base substrate 121, the cost can be reduced as compared to the case of using a single crystal silicon substrate or the like.

Alternatively, as the base substrate 121, a substrate which is formed of an insulator, such as a ceramic substrate, a quartz substrate, or a sapphire substrate, a substrate which is formed of a conductor such as metal or stainless steel, or the like may be used. Note that any of the above substrates given as examples of the semiconductor substrate 111, or the like may be used. Alternatively, a plastic substrate capable of resisting processing temperature in a manufacturing process may be used as the base substrate 121. In this embodiment, the case of using a glass substrate as the base substrate 121 will be described.

Note that an insulating film may be formed over the base substrate 121. When an insulating film is formed over the base substrate 121, a method and a material which are similar to those of the insulating film 112 can be used for the insulating film. In the case where a silicon oxide film is formed as the insulating film 112 on the semiconductor substrate 111 to a thickness of 100 nm by a thermal oxidation method, a silicon nitride oxide film may be formed as the insulating film over the base substrate 121 to a thickness of 50 nm by a CVD method.

Next, at least one of the semiconductor substrate 111 and the base substrate 121 is preferably subjected to surface treatment. When the surface treatment is performed, the bonding strength at the bonding interface between the semiconductor substrate 111 and the base substrate 121 can be increased. In addition, the surface treatment makes it possible to reduce particles on the substrate; thus, bonding defects due to particles can be reduced.

As examples of the surface treatment, wet treatment, dry treatment, and a combination of both can be given. Further, a different wet treatment combination and a different dry treatment combination can be given.

As examples of the wet treatment, ozone treatment using ozone water (treatment with ozone water), megasonic cleaning using an alkaline cleaner, brush cleaning, two-fluid cleaning (a method in which functional water such as pure water or hydrogenated water and a carrier gas such as nitrogen are sprayed together), and the like can be given. As examples of the dry treatment, irradiation with light from a Xe excimer UV lamp, plasma treatment, plasma treatment with bias application, and radical treatment can be given.

In this embodiment, as the surface treatment, the dry treatment and the wet treatment are performed in combination on the semiconductor substrate 111 and the base substrate 121. First, as the dry treatment, irradiation using a Xe excimer UV lamp is performed in an atmosphere containing oxygen. After that, as the wet treatment, megasonic cleaning with an alkaline cleaner is performed.

Then, the semiconductor substrate 111 and the base substrate 121 are bonded to each other with the insulating film 112 interposed therebetween (see FIG. 1C). For example, the base substrate 121 and the semiconductor substrate 111 provided with the insulating film 112 are placed so as to face each other and are bonded to each other. Although the semiconductor substrate 111 provided with the insulating film 112 is bonded to the base substrate 121 in this embodiment, one embodiment of the present invention is not limited thereto. An insulating film formed over the base substrate 121 and the insulating film 112 formed on the semiconductor substrate 111 may be bonded to each other.

Note that before the semiconductor substrate 111 is bonded to the base substrate 121, at least one of the semiconductor substrate 111 and the base substrate 121 may be heated.

Next, heat treatment is performed on the semiconductor substrate 111 and the base substrate 121 which have been bonded to each other. Accordingly, the bonding strength between the semiconductor substrate 111 and the base substrate 121 can be increased. The heat treatment temperature needs to be a temperature at which separation along the embrittlement region 113 does not occur. For example, the temperature is set to lower than 400° C., preferably lower than or equal to 300° C. Heat treatment time is not particularly limited and may be set as appropriate depending on the relation between processing time and bonding strength. The heat treatment can be performed using a diffusion furnace or a heating furnace such as a resistance heating furnace, a rapid thermal annealing (RTA) apparatus, or the like. Further, only the bonding region may be locally heated by irradiation with microwaves or the like. When there is no problem in bonding strength, the heat treatment may be omitted. In this embodiment, the heat treatment is performed at 200° C. for two hours.

After that, heat treatment is performed on the semiconductor substrate 111 and the base substrate 121 which have been bonded to each other. Consequently, the semiconductor substrate 111 is separated along the embrittlement region 113 into a semiconductor substrate 115 and a semiconductor film 114 provided over the base substrate 121 with the insulating film 122 interposed therebetween (see FIG. 1D). Thus, the SOI substrate in which the semiconductor film 114 is provided over the base substrate 121 with the insulating film 122 interposed therebetween can be obtained.

When the heat treatment is performed, the added hydrogen atoms are extracted in microvoids which are formed in the embrittlement region 113 due to an increase in temperature, and the internal pressure of the microvoids is increased. The increase in pressure changes the volume of the microvoids in the embrittlement region 113, so that the semiconductor substrate 111 is separated into the semiconductor film 114 and the semiconductor substrate 115 along the embrittlement region 113. Since the insulating film 112 is bonded to the base substrate 121, the semiconductor film 114 into which the semiconductor substrate 111 is separated is provided over the base substrate 121 with the insulating film 122 interposed therebetween.

This heat treatment is performed at a temperature not exceeding the strain point of the base substrate 121. For example, in the case where a glass substrate is used as the base substrate 121, the heat treatment is preferably performed at a temperature in the range of 400° C. to 750° C. However, the temperature range of the heat treatment is not limited thereto as long as a glass substrate can withstand exposure to a temperature higher than the above range. For this heat treatment, a diffusion furnace, a heating furnace such as a resistance heating furnace, a rapid thermal annealing (RTA) apparatus, a microwave heating apparatus, or the like can be used. Note that in this embodiment, the heat treatment is performed at 600° C. for two hours.

Note that heat treatment for increasing the bonding strength between the semiconductor substrate 111 and the base substrate 121 is not necessarily performed, and heat treatment for separation along the embrittlement region 113 may double as the heat treatment for increasing the bonding strength between the semiconductor substrate 111 and the base substrate 121.

Then, a portion where the bonding strength between the insulating film 122 and the base substrate 121 is low (part of the periphery of the semiconductor film 114) is removed at the bonding interface between the insulating film 122 and the base substrate 121. A method for removing part of the semiconductor film 114 will be described below with reference to FIGS. 2A to 2E.

FIG. 2A illustrates the semiconductor film 114 provided over the base substrate 121 with the insulating film 122 interposed therebetween.

Next, a resist mask 130 is formed so as to cover the semiconductor film 114 and the insulating film 122 (see FIG. 2B). For example, after the semiconductor film 114 is coated with a resist, a photomask is set in a light-exposure apparatus and light is cast on the resist, so that the resist is exposed to light. Then, the resist is developed so that a resist mask 131 can be formed (see FIG. 2C).

The resist mask 131 is preferably tapered. Further, part of the semiconductor film 114 and part of the insulating film 122 are preferably exposed.

After that, etching treatment is performed to remove part of the semiconductor film 114 and part of the insulating film 122. As this etching treatment, dry etching is preferably employed. Dry etching is performed using a parallel-plate reactive ion etching (RIE) apparatus.

The conditions for etching of the semiconductor film 114 and the insulating film 122 may be set as follows: the bias power of a parallel plate is 300 W; the pressure inside a chamber is 26.66 Pa; the gas flow ratio of SF₆ to He is 20:20 (sccm); and the etching time is approximately 180 seconds.

When the semiconductor film 114 and the insulating film 122 are etched as described above, the semiconductor film 117 and the insulating film 118 can be formed so that the periphery of the insulating film 118 and the periphery of the semiconductor film 117 are on the inner side than the periphery of the base substrate 121, and the periphery of the semiconductor film 117 is on the inner side than the insulating film 118. The taper angle of the insulating film 118 (a in FIG. 2E in this case) can be larger than or equal to 3° and smaller than or equal to 60°, preferably larger than or equal to 3° and smaller than or equal to 45°. Accordingly, it is possible to suppress side etching due to a difference between the etching rate of the insulating film 122 and the etching rate of the base substrate 121 in a cleaning step or wet etching treatment; thus, removal of part of the base substrate between the insulating film 122 and the base substrate 121 can be suppressed. Consequently, part or the whole of a semiconductor film 117 can be prevented from peeling off the base substrate 121. The reason thereof will be given below.

In the structure where a semiconductor film is provided over a base substrate with an insulating film interposed therebetween, there is a difference between the stress of the semiconductor film to the base substrate and the stress of the insulating film to the base film in some cases. This difference in stress might cause the peripheries of the semiconductor film and the insulating film to be warped upward. Such warping occurs, for example, in the case where tensile stress is applied to the semiconductor film and compressive stress is applied to the insulating film, the case where compressive stresses are applied to both the semiconductor film and the insulating film and the compressive stress of the insulating film is higher than that of the semiconductor film, or the case where tensile stresses are applied to both the semiconductor film and the insulating film and the tensile stress of the semiconductor film is higher than that of the insulating film.

In these cases, it is advantageously effective to perform processing so that the periphery of the semiconductor film is on the inner side than the periphery of the insulating film, in order to prevent peeling of part or the whole of the semiconductor film and the insulating film from the base substrate.

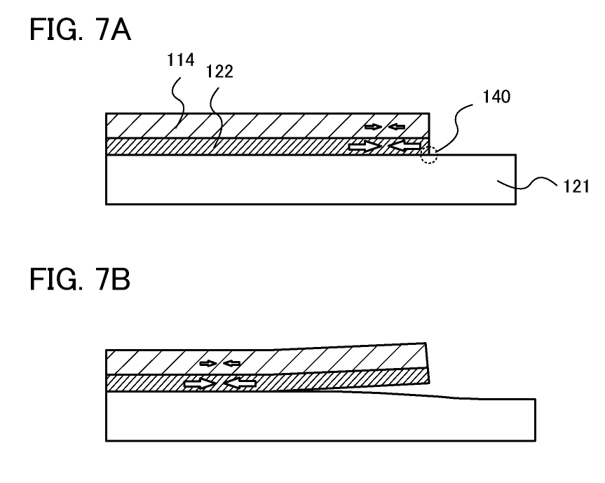

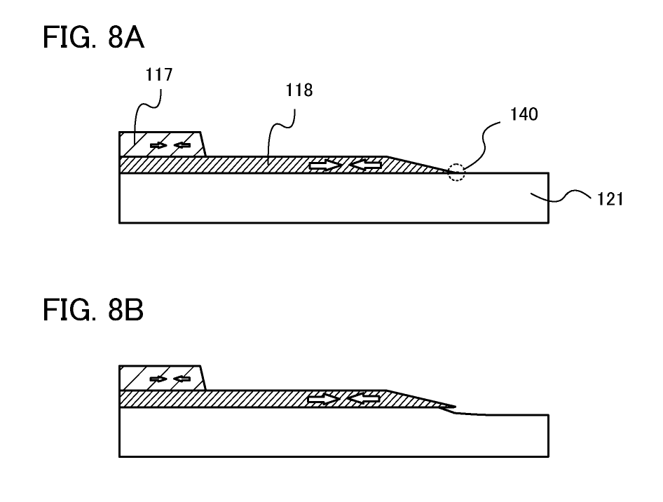

In this embodiment, the case where compressive stresses are applied to both the semiconductor film and the insulating film and the compressive stress of the insulating film is higher than that of the semiconductor film is given as an example and will be described below with reference to FIGS. 7A and 7B and FIGS. 8A and 8B.

First, FIG. 7A illustrates the case where part of the semiconductor film 114 is not removed. The arrows in the drawings show compressive stresses and the size of the arrow shows the strength of the stress. In this case, the semiconductor film 114 is in contact with the insulating film 122 also on the periphery of the semiconductor film 114.

In the relation between the base substrate 121 and the insulating film 122, the compressive stress of the insulating film 122 serves as stress which causes the base substrate 121 to be warped upward.

On the other hand, in the relation between the semiconductor film 114 and the insulating film 122, the difference in compressive stress causes the peripheries of the semiconductor film 114 and the insulating film 122 to be warped upward.

Therefore, when treatment with hydrofluoric acid is performed in this state, part of the base substrate 121, which is in contact with the end of the insulating film 122, is etched and thus a portion 140 between the insulating film 122 and the base substrate 121 is cracked. The crack caused between the insulating film 122 and the base substrate 121 results in loss of the stress caused by the relation between the base substrate 121 and the insulating film 122, which has caused the base substrate 121 to be warped upward. However, in the relation between the semiconductor film 114 and the insulating film 122, the stress which causes the peripheries of the semiconductor film 114 and the insulating film 122 to be warped upward has occurred; thus, the stress is concentrated on the crack. When the semiconductor film 114 and the insulating film 122 are warped, stress is released. As a result, hydrofluoric acid enters the crack between the insulating film 122 and the base substrate 121 and the crack is easily widened.

Consequently, the peripheries of the semiconductor film 114 and the insulating film 122 peel off the base substrate 121 (FIG. 7B). The part peeling off the base substrate 121 is more likely to trigger peeling than any other part when mechanical force is applied.

Next, FIG. 8A illustrates the case where part of the semiconductor film 117 is removed. In this case, the periphery of the semiconductor film 117 is not in contact with the periphery of the insulating film 118. Thus, stress which causes upward warping on the periphery of the insulating film 118 due to a difference in stress is reduced.

Even when treatment with hydrofluoric acid is performed in this state and a crack is caused between the insulating film 118 and the base substrate 121, the insulating film 118 is not likely to be warped. Accordingly, the crack is not easily widened, which leads to prevention of peeling of part or the whole of the semiconductor film 117 and the insulating film 118 from the base substrate 121 (FIG. 8B).

Note that at least a slight portion of the periphery of the semiconductor film 117 needs to be on the inner side than the insulating film 118. Note that if a portion where only the insulating film 118 is provided is too wide, a region which can be used as an SOI substrate is small. Thus, the distance between the end of the semiconductor film 117 and the end of the insulating film 118 is, for example, preferably 50 μm or less, more preferably 5 μm or less.

Although FIGS. 7A and 7B and FIGS. 8A and 8B illustrate the cases where compressive stresses are applied to both the semiconductor film and the insulating film and the compressive stress of the insulating film is higher than that of the semiconductor film, the advantageous effect obtained by performing processing so that the periphery of the semiconductor film 117 is on the inner side of the periphery of the insulating film 118 can be achieved not only in this case. In other words, similar effects can be achieved in the case where tensile stress and compressive stress are applied to a semiconductor film and an insulating film, respectively, and in the case where tensile stresses are applied to both a semiconductor film and an insulating film and the tensile stress of the semiconductor film is higher than that of the insulating film.

The taper angle of the periphery of the semiconductor film 117 (β in FIG. 2E in this case) can be larger than or equal to 30° and smaller than or equal to 90°.

Next, the semiconductor film 117 of the SOI substrate 100 may be subjected to planarization treatment. Even when a surface of the semiconductor film 117 is uneven due to the ion exposing step or the separating step, the surface of the semiconductor film 117 can be planarized by the planarization treatment.

The planarization treatment can be performed by chemical mechanical polishing (CMP) treatment, etching treatment, laser light irradiation, or the like. Here, the semiconductor film 117 is irradiated with laser light, whereby the surface of the semiconductor film 117 can be planarized. Further, the semiconductor film 117 can be recrystallized, resulting in improvement in crystallinity of the semiconductor film 117.

Before the laser light irradiation of the semiconductor film 117, an oxide film on the surface of the semiconductor film 117 is removed with hydrofluoric acid. The SOI substrate in this embodiment has a structure where both the periphery of the insulating film and the periphery of the semiconductor film are on the inner side than the periphery of the base substrate, and the periphery of the semiconductor film is on the inner side than the periphery of the insulating film. In addition, the taper angle of the insulating film is larger than or equal to 3° and smaller than or equal to 60°, preferably larger than or equal to 3° and smaller than or equal to 45°. Accordingly, it is possible to suppress side etching due to a difference between the etching rate of the insulating film and the etching rate of the base substrate in a cleaning step with hydrofluoric acid; thus, removal of part of the base substrate 121 between the insulating film 118 and the base substrate 121 can be suppressed. Consequently, the oxide film formed on the surface of the semiconductor film 117 can be partly removed while part or the whole of a semiconductor film 117 can be prevented from peeling off the base substrate 121.

By irradiation with laser light through the top surface of the semiconductor film 117, the top surface of the semiconductor film 117 is melted. After being melted, the semiconductor film 117 is cooled and solidified, so that the flatness of the surface of a semiconductor film 117 can be improved. With the use of laser light, the base substrate 121 is not directly heated; thus, an increase in temperature of the base substrate 121 can be suppressed. Accordingly, a substrate having a low heat resistance, such as a glass substrate, can be used as the base substrate 121.

Note that it is preferable that the semiconductor film 117 be partly melted by laser light irradiation. This is because complete melting leads to microcrystallization due to generation of random nuclei following a change to a liquid phase, bringing a high possibility of a reduction in crystallinity. On the other hand, by partial melting, crystal growth proceeds from a non-melted solid phase part. Accordingly, defects in the semiconductor film 117 can be reduced. Note that “complete melting” here means that the semiconductor film 117 is melted up to the vicinity of the lower interface of the semiconductor film 117 to be in a liquid state. On the other hand, “partial melting” in this case means that an upper part of the semiconductor film 117 is melted to be in a liquid phase whereas a lower part thereof is kept in a solid phase without being melted.

A pulsed laser is preferably used for the laser light irradiation. This is because high-energy pulsed laser light can be emitted instantaneously and a melting state can be easily obtained. The repetition rate is preferably approximately higher than or equal to 1 Hz and lower than or equal to 10 MHz.

After the laser light irradiation, a step of reducing the thickness of the semiconductor film 117 may be performed. To thin the semiconductor film 117, etching treatment (etchback treatment) may be performed by dry etching, wet etching, or a combination of both. For example, in the case where the semiconductor film 117 is formed using a silicon material, the semiconductor film 117 can be thinned by dry etching using SF₆ and O₂ for an etching gas.

Note that although the case where the laser light irradiation of the semiconductor film 117 precedes the etching treatment in this embodiment, one embodiment of the present invention is not limited thereto. The etching treatment may be performed before the laser light irradiation, or both before and after the laser light irradiation.

Note that not only the SOI substrate 100 but also the semiconductor substrate 115 after separation may be subjected to planarization treatment. Planarization of a surface of the semiconductor substrate 115 after separation makes it possible to reuse the semiconductor substrate 115 in a process for manufacturing the SOI substrate.

Through the above steps, the semiconductor film 117 can be provided over the base substrate 121 with the insulating film 118 interposed therebetween.

By the method described in this embodiment, a semiconductor film such as a single crystal silicon film can be prevented from peeling off a base substrate. Moreover, this method makes it possible to increase the yield and reduce manufacturing cost in manufacture of SOI substrates.

Next, a method for removing part of the semiconductor film 114 and part of the insulating film 122 with an atmospheric pressure plasma etching apparatus, which is different from the method illustrated in FIGS. 2A to 2E, will be described with reference to FIGS. 3A and 3B.

FIG. 3A illustrates a structural example of an atmospheric pressure plasma etching apparatus. The atmospheric pressure plasma etching apparatus in FIG. 3A includes a main body 410, a plasma generation source 411, an exit 412, an exit 413, an exit 414, and an exhaust port 416. The plasma generation source 411 generates plasma in an atmospheric pressure or substantially atmospheric pressure atmosphere. From the exit 412, the plasma generated in the plasma generation source 411 is released to the outside. From the exit 413, an etching gas is released. From the exit 414, a sheath gas is released. As an etching gas, a gas can be selected as appropriate depending on objects to be processed which are subjected to etching (the semiconductor film 114 and the insulating film 122). For example, SF₆ can be used as the etching gas. As the sheath gas, Ar or N₂ can be used. Note that the etching gas and the sheath gas can be supplied from the outside to the main body 410 or can be stored in a tank 415 provided in the main body 410.

The atmospheric pressure plasma etching apparatus in FIG. 3A mixes the plasma (e.g., Ar plasma) released from the exit 412 and the etching gas (e.g., SF₆) released from the exit 413 to produce etch species in the plasma and an object to be processed is etched by the etch species. Further, release of the sheath gas (e.g., N₂) from the exit 414 allows prevention of mixing of the air into the etch species produced in the plasma. In the atmospheric pressure plasma etching apparatus in FIG. 3A, data may be input to the main body 410 with the use of an optical monitor. The main body 410 controls operation of the plasma generation source 411 on the basis of the data. Through the above steps, the objects to be processed (the semiconductor film 114 and the insulating film 122) can be etched in the atmospheric pressure plasma etching apparatus in FIG. 3A. The exhaust port 416 is preferably provided in the vicinity of the exits 412 to 414 so that a by-product produced by etching of the object to be processed can be exhausted.

Subsequently, a specific example of operation of the atmospheric pressure plasma etching apparatus in FIG. 3A will be described in FIG. 3B. FIG. 3B is a flow chart showing the example of operation performed in etching objects to be processed (the semiconductor film 114 and the insulating film 122). As in FIG. 3B, when the etching process is started, etch species are produced. Then, whether objects to be processed (the semiconductor film 114 and the insulating film 122) exist is determined by the optical monitor. In accordance with this result, whether the production of the etch species is continued (whether the etching process is continued) is determined. Accordingly, in the atmospheric pressure plasma etching apparatus in FIG. 3A, underetching or overetching can be suppressed.

Further, in the atmospheric pressure plasma etching apparatus of FIG. 3A, the exit 413 from which the etching gas is released is provided so as to surround the exit 412 from which the plasma is released. In addition, the exit 414 from which the sheath gas is released is provided so as to surround the exit 413 from which the etching gas is released. Thus, a region where the etch species are produced in the plasma is not widened, and only a desired region can be etched. Accordingly, part of the insulating film 122 and part of the semiconductor film 114 can be removed by atmospheric pressure plasma etching.

### Embodiment 2

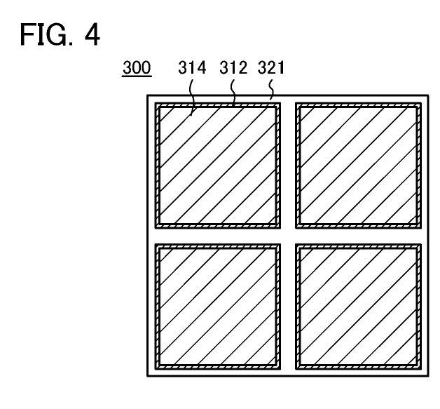

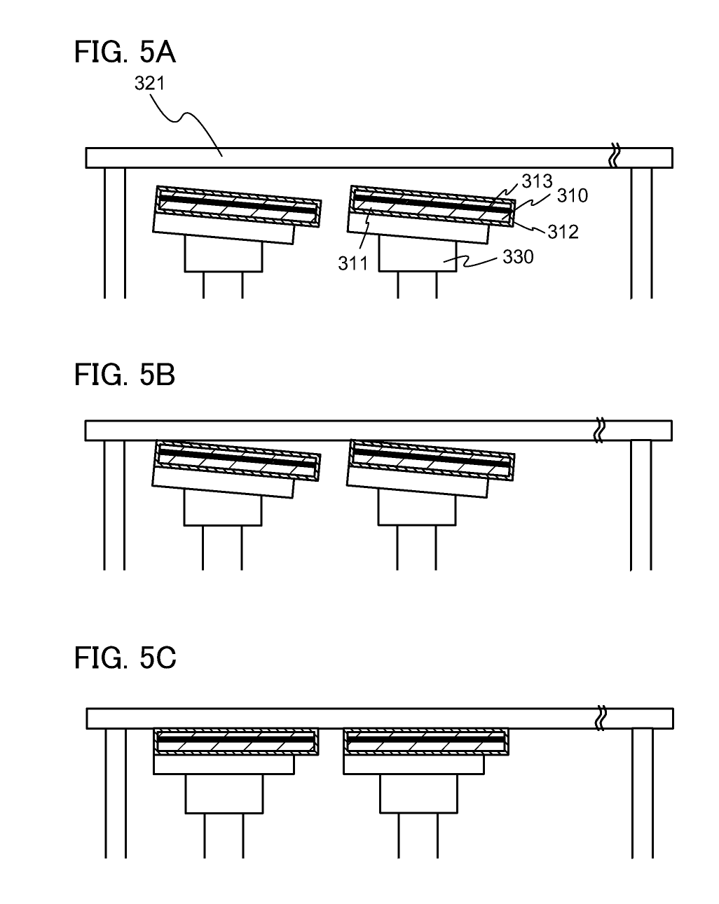

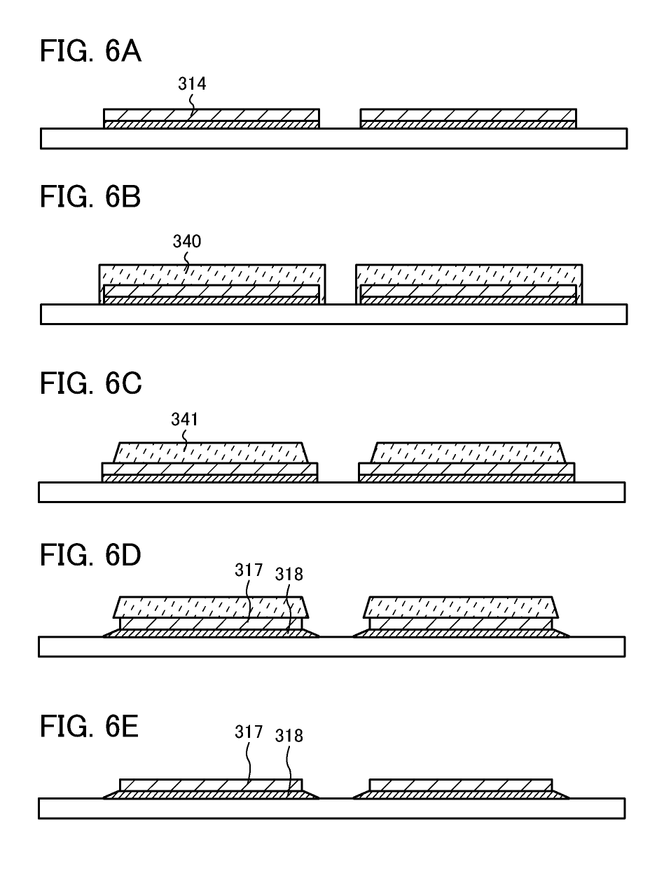

In this embodiment, an SOI substrate which is different from that in Embodiment 1 and a manufacturing method thereof will be described with reference to FIG. 4, FIGS. 5A to 5C, and FIGS. 6A to 6E.

FIG. 4 is a perspective view illustrating a structural example of an SOI substrate 300. In the SOI substrate 300, a plurality of semiconductor films 317 are bonded to one base substrate 321. The semiconductor films 317 are each provided over the base substrate 321 with insulating films 318 interposed therebetween.

A method for manufacturing the SOI substrate 300 in FIG. 4 will be described with reference to FIGS. 5A to 5C, and FIGS. 6A to 6E. Embodiment 2 is different from Embodiment 1 in that the plurality of semiconductor films 314 are attached to one base substrate 321. Therefore, this point will be mainly described below.

First, the base substrate 321 is prepared. As the base substrate 321, a mother glass substrate which has been developed for manufacturing liquid crystal panels is preferably used. As such a mother glass substrate, substrates having the following sizes are known: the third generation (550 mm×650 mm), the 3.5-th generation (600 mm×720 mm), the fourth generation (680 mm×880 mm, or 730 mm×920 mm), the fifth generation (1100 mm×1300 mm), the sixth generation (1500 mm×1850 mm), the seventh generation (1870 mm×2200 mm), the eighth generation (2200 mm×2400 mm), the ninth generation (2400 mm×2800 mm, or 2450 mm×3050 mm), and the tenth generation (2950 mm×3400 mm), and the like.

When a large mother glass substrate is used as the base substrate 321, the area of the SOI substrate 300 can be large. The increase in the area of the SOI substrate 300 allows many panels such as liquid crystal panels or many chips such as ICs or LSIs to be manufactured from one SOI substrate 300; thus, the number of panels or chips manufactured from one substrate is increased, resulting in a significant increase in productivity.

Note that an insulating film may be formed over the base substrate 321. To form the insulating film over the base substrate 321, a method and a material which are similar to those of the insulating film 112 described in Embodiment 1 can be used; thus, specific description is omitted.

Next, a plurality of semiconductor substrates 311 are prepared. In this embodiment, the semiconductor substrate 311 is processed to have a desired size and a desired shape. Considering the fact that the shape of the base substrate 321 to which the semiconductor substrates 311 are bonded is rectangular and a light-exposing region of a light exposure apparatus such as a reduced-projection light exposure apparatus is rectangular, the shape of the semiconductor substrate 311 is preferably rectangular. For example, the semiconductor substrate 311 having a rectangular shape is preferably processed so that the length of a long side thereof is n times (n is a given positive integer) that of one side of a region to be exposed to light of one shot from a reduced-projection light exposure apparatus.

The rectangular semiconductor substrate 311 can be formed by cutting a circular bulk semiconductor substrate. The semiconductor substrate 311 can be cut by laser cutting, plasma cutting, electronic beam cutting, or with a cutting device such as a dicer or a wire saw or any cutting means. Alternatively, before being sliced into the semiconductor substrate 311, an ingot for manufacturing semiconductor substrates can be processed into a rectangular solid so that it has a rectangular cross section, and this ingot that is a rectangular solid may be sliced to manufacture the rectangular semiconductor substrate 311.

Next, the insulating film 312 is formed on each of the plurality of semiconductor substrates 311. After that, each of the plurality of semiconductor substrates 311 is exposed to ions, whereby an embrittlement region 313 is formed in the semiconductor substrate 311. The steps are similar to those of FIGS. 1A1 to 1A3, and thus the detail thereof are omitted.

Next, at least the plurality of semiconductor substrates 311 or the base substrate 321 is preferably subjected to surface treatment. The surface treatment step is similar to that of Embodiment 1, and thus the detail thereof is omitted.

Then, the plurality of semiconductor substrates 311 are bonded to the base substrate 321. Specifically, the base substrate 321 and the semiconductor substrates 311 are placed so as to face each other, and the base substrate 321 and the insulating films 312 which are formed on the semiconductor substrates 311 are bonded to each other. A method for bonding the base substrate 321 and the plurality of semiconductor substrates 311 will be described with reference to FIGS. 5A to 5C.

First, the base substrate 321 is provided over and close to each of the semiconductor substrates 311 mounted on jigs 330 at a small interval (approximately several millimeters) (see FIG. 5A). At this time, the base substrate 321 and each of surfaces of the semiconductor substrates 311, in which the embrittlement regions 313 are formed, are provided to face each other. Further, with the use of the jigs 330, the semiconductor substrates 311 are preferably provided to be slightly tilted with respect to the base substrate 321 (at about an angle of several degrees). The semiconductor substrates 311 are placed close to the base substrate 321 while being tilted, whereby initial contact points between the base substrate 321 and the semiconductor substrates 311 can be bonding start points, leading to stable bonding. Note that there is no particular limitation on the interval and the angle between the base substrate 321 and the semiconductor substrate 311, which are set as appropriate depending on the bonding.

Then, the base substrate 321 is pressed so that the base substrate 321 and ends of the semiconductor substrates 311 are in contact with each other (see FIG. 5B). Alternatively, with the use of a pin or the like, a point of the base substrate 321 or the semiconductor substrate 311, for example, a central portion of the base substrate 321 is pressed, whereby the base substrate 321 may be in contact with the semiconductor substrates 311. The base substrate 321 and the semiconductor substrates 311 start to be bonded to each other from a portion where they are in contact with each other, and then bonding is spontaneously generated over the entire surface (see FIG. 5C).

Although two semiconductor substrates 311 are bonded to the base substrate 321 with the use of two jigs in this embodiment, one embodiment of the present invention is not limited to thereto. The plurality of semiconductor substrates 311 may be sequentially bonded using one jig or the plurality of semiconductor substrates may be sequentially bonded using a plurality of jigs. When the plurality of semiconductor substrates 311 are bonded using a plurality of jigs, the plurality of semiconductor substrates 311 can be bonded all at once.

Next, by performing heat treatment, the semiconductor substrate 311 is separated into a semiconductor film 314 and a semiconductor substrate 310 along the embrittlement region 313. Through the above steps, an SOI substrate in which the plurality of semiconductor films 314 are provided over the base substrate 321 can be obtained (see FIG. 6A). The steps are similar to those of Embodiment 1, and thus the detail thereof is omitted.

After that, as in the above embodiment, a resist mask 340 is formed so as to cover each of the plurality of semiconductor substrates 311 (see FIG. 6B). For example, after the semiconductor films 314 are coated with resists, a photomask is set in a light-exposure apparatus and light is projected on the resists, so that the resists are exposed to light. Then, the resists are developed so that resist masks 341 can be formed (see FIG. 6C).

The resist masks 341 are preferably tapered. Further, parts of the semiconductor films 314 and parts of the insulating films 312 are preferably exposed.

After that, etching treatment is performed to remove part of the semiconductor film 314 and part of the insulating film 312. As this etching treatment, dry etching is preferably employed. Dry etching is performed using a parallel-plate reactive ion etching (RIE) apparatus.

The conditions for etching of the semiconductor film 314 and the insulating film 312 may be set as follows: the bias power of the parallel plate is 300 W; the pressure inside a chamber is 26.66 Pa; the gas flow ratio of SF₆ to He is 20:20 (sccm); and the etching time is approximately 180 seconds.

The semiconductor film 314 and the insulating film 312 are etched as described above; whereby a semiconductor film 317 and an insulating film 318 are formed so that the periphery of the insulating film 312 and the periphery of the semiconductor film 314 can be on the inner side than the periphery of the base substrate 321, and the periphery of the semiconductor film 314 can be on the inner side than the insulating film 312 (see FIG. 6D). The taper angle of the insulating film 318 can be larger than or equal to 3° and smaller than or equal to 60°, preferably larger than or equal to 3° and smaller than or equal to 45°. Accordingly, it is possible to suppress side etching due to a difference between the etching rate of the insulating film 318 and the etching rate of the base substrate 321 in a cleaning step or a wet etching treatment; thus, removal of part of the base substrate between the insulating film 318 and the base substrate 321 can be suppressed. Consequently, part or the whole of a semiconductor film 317 can be prevented from peeling off the base substrate 321.

The taper angle of the periphery of the semiconductor film 317 can be larger than or equal to 30° and smaller than or equal to 90°.

Next, the semiconductor film 317 of the SOI substrate 300 may be subjected to planarization treatment. Even when a surface of the semiconductor film 317 is uneven due to the ion exposing step or the separating step, the surface of the semiconductor film 317 can be planarized by the planarization treatment.

The planarization treatment can be performed by CMP treatment, etching treatment, laser light irradiation, or the like. Here, the semiconductor film 317 is irradiated with laser light, whereby the surface of the semiconductor film 317 can be planarized. Further, the semiconductor film 317 can be recrystallized, resulting in improvement in crystallinity of the semiconductor film 317.

Through the above steps, the SOI substrate 300 in which the plurality of semiconductor films 314 are bonded to one base substrate 321 in FIG. 4 can be obtained.

### Embodiment 3

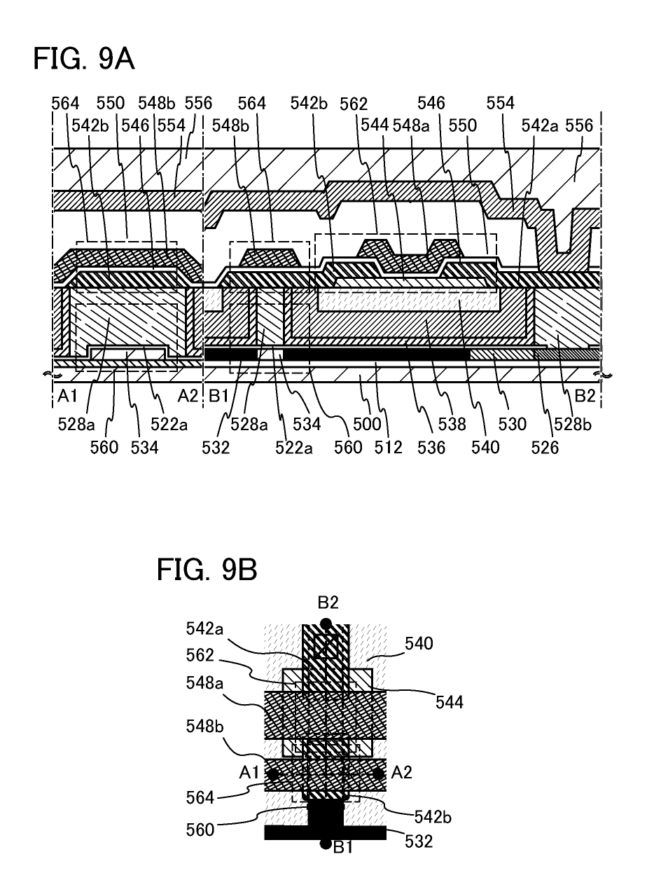

In this embodiment, a structure of a semiconductor device formed using an SOI substrate according to one embodiment of the present invention will be described with reference to FIGS. 9A and 9B.

FIGS. 9A and 9B illustrate a structure example of the semiconductor device formed using an SOI substrate according to one embodiment of the present invention. The semiconductor device illustrated in FIGS. 9A and 9B can be used as a memory cell.

FIG. 9A illustrates a cross section of the semiconductor device, and FIG. 9B illustrates a plan view of the semiconductor device. Here, FIG. 9A corresponds to cross sections along A1-A2 and B1-B2 of FIG. 9B.

The semiconductor device illustrated in FIGS. 9A and 9B includes a transistor 560 formed using a first semiconductor material in its lower portion and a transistor 562 formed using a second semiconductor material in its upper portion. Here, the first semiconductor material is preferably different from the second semiconductor material. For example, a semiconductor material other than an oxide semiconductor can be used as the first semiconductor material, and an oxide semiconductor can be used as the second semiconductor material.

The semiconductor material other than an oxide semiconductor can be, for example, silicon, germanium, silicon germanium, silicon carbide, gallium arsenide, or the like and is preferably single crystalline. A transistor formed using such a semiconductor material other than an oxide semiconductor can operate at high speed easily.

On the other hand, as the oxide semiconductor, an In—Ga—Zn—O-based oxide semiconductor material or an In—Zn—O-based oxide semiconductor material can be used. It is preferable that the oxide semiconductor be highly purified by reducing an impurity such as hydrogen contained in the oxide semiconductor. When the oxide semiconductor obtained in such a manner is used for a transistor, the off-state current of the transistor can be significantly reduced. The use of the transistor whose off-state current is extremely low for a memory cell enables long storage of charge.

It is possible to use an SOI substrate in which a semiconductor film is provided over a base substrate 500 with an insulating film 512 interposed therebetween as in FIG. 9A. As such an SOI substrate, the SOI substrate according to the above embodiment of the present invention can be used. In the SOI substrate according to one embodiment of the present invention, neither part or the whole of the semiconductor film peels off the base substrate 500, so that the yield can be increased and the manufacturing cost can be reduced also in manufacture of semiconductor devices.

The transistor 560 in FIGS. 9A and 9B includes a channel formation region 534 provided in the semiconductor film over the base substrate 500, impurity regions 532 (also referred to as a source region and a drain region) between which the channel formation region 534 is provided, a gate insulating film 522a provided over the channel formation region 534, and a gate electrode 528a provided over the gate insulating film 522a so as to overlap with the channel formation region 534.

Note that FIGS. 9A and 9B illustrate an element in which distinct source and drain electrodes are not provided; the element in such a state is sometimes referred to as a transistor for the sake of convenience. Further, in such a case, in description of a connection of a transistor, a source region and a source electrode are collectively referred to as a “source electrode,” and a drain region and a drain electrode are collectively referred to as a “drain electrode”. That is, the term “source electrode” in this specification may include a source region.

Further, a conductive layer 528b is connected to an impurity region 526 provided in the semiconductor film over the base substrate 500. Here, the conductive layer 528b functions as a source electrode or a drain electrode of the transistor 560. In addition, an impurity region 530 is provided between the impurity region 532 and the impurity region 526. Further, an insulating film 536, an insulating film 538, and an insulating film 540 are provided so as to surround the transistor 560. Note that it is preferable that the transistor 560 do not include sidewall insulating films as illustrated in FIG. 9A in order to increase the scale of integration. On the other hand, in the case where the characteristics of the transistor 560 have priority, sidewall insulating films may be provided on side surfaces of the gate electrode 528a, and the impurity regions 532 may each include a region with a different impurity concentration.

The transistor 562 in FIGS. 9A and 9B includes an oxide semiconductor layer 544, a source (drain) electrode 542a, a drain (source) electrode 542b, a gate insulating film 546, and a gate electrode 548a. The oxide semiconductor layer 544 is provided over the insulating film 540 and the like. The source and drain electrodes 542a and 542b are electrically connected to the oxide semiconductor layer 544. The gate insulating film 546 covers the oxide semiconductor layer 544 and the source and drain electrodes 542a and 542b. The gate electrode 548a is provided over the gate insulating film 546 so as to overlap with the oxide semiconductor layer 544.

Here, it is preferable that the oxide semiconductor layer 544 be highly purified by sufficient reduction of impurities such as hydrogen or sufficient supply of oxygen. Specifically, the hydrogen concentration in the oxide semiconductor layer 544 is lower than or equal to 5×10¹⁹ atoms/cm³, preferably lower than or equal to 5×10¹⁸ atoms/cm³, more preferably lower than or equal to 5×10¹⁷ atoms/cm³, for example. Note that the hydrogen concentration in the oxide semiconductor layer 544 is measured by secondary ion mass spectrometry (SIMS). In the oxide semiconductor layer 544 highly purified by sufficiently reducing the hydrogen concentration therein and in which defect levels in an energy gap due to oxygen vacancies are reduced by supplying a sufficient amount of oxygen, the carrier concentration is lower than 1×10¹²/cm³, preferably lower than 1×10¹¹/cm³, more preferably lower than 1.45×10¹°/cm³. For example, the off-state current (here, current per micrometer (μm) in channel width) at room temperature (25° C.) is lower than or equal to 100 zA (1 zA (zeptoampere)=1×10⁻²¹ A), preferably lower than or equal to 10 zA. When such an i-type (intrinsic) or substantially i-type oxide semiconductor is used, the off-state current of the transistor 562 can be extremely low.

Although the oxide semiconductor layer 544 processed into an island shape is used in the transistor 562 in FIGS. 9A and 9B in order to reduce leakage current generated between elements due to miniaturization, the oxide semiconductor layer 544 is not necessarily processed into an island shape. In the case where the oxide semiconductor layer 544 is not processed into an island shape, contamination of the oxide semiconductor layer 544 due to etching in the processing can be prevented.

A capacitor 564 in FIGS. 9A and 9B includes the drain electrode 542b, the gate insulating film 546, and a conductive layer 548b. That is, the drain electrode 542b functions as one electrode of the capacitor 564, and the conductive layer 548b functions as the other electrode of the capacitor 564. With such a structure, capacitance can be sufficiently secured. Further, when the oxide semiconductor layer 544 and the gate insulating film 546 are stacked, insulation between the drain electrode 542b and the conductive layer 548b can be sufficiently secured. In the case where a capacitor is not needed, the capacitor 564 may be omitted.

In this embodiment, the transistor 562 and the capacitor 564 are provided so as to overlap with the transistor 560 at least partly. When such a planar layout is employed, high integration can be realized. For example, given that the minimum feature size is F, the area occupied by a memory cell can be 15F² to 25F².

An insulating film 550 is provided over the transistor 562 and the capacitor 564. In an opening formed in the gate insulating film 546 and the insulating film 550, a wiring 554 is provided. The wiring 554 connects one memory cell to another memory cell. The wiring 554 is connected to the impurity region 526 through the source electrode 542a and the conductive layer 528b. The above structure allows a reduction in number of wirings in comparison with a structure in which the source region or the drain region in the transistor 560 and the source electrode 542a in the transistor 562 are connected to different wirings. Thus, the scale of integration of a semiconductor device can be increased.

When the conductive layer 528b is provided, a position where the impurity region 526 and the source electrode 542a are connected and a position where the source electrode 542a and the wiring 554 are connected can overlap with each other. With such a planar layout, the element area can be prevented from increasing due to contact regions. In other words, the scale of integration of the semiconductor device can be increased. Note that an insulating film 556 may be provided over the wiring 554.

A plurality of the semiconductor devices (memory cells) in FIGS. 9A and 9B are connected in series, whereby a NAND memory cell array can be formed. On the other hand, when the semiconductor devices are connected in parallel, a NOR memory cell array can be formed.

The use of an SOI substrate according to one embodiment of the present invention for semiconductor devices makes it possible to increase the yield and reduce the manufacturing cost in manufacture of semiconductor devices.

### Embodiment 4

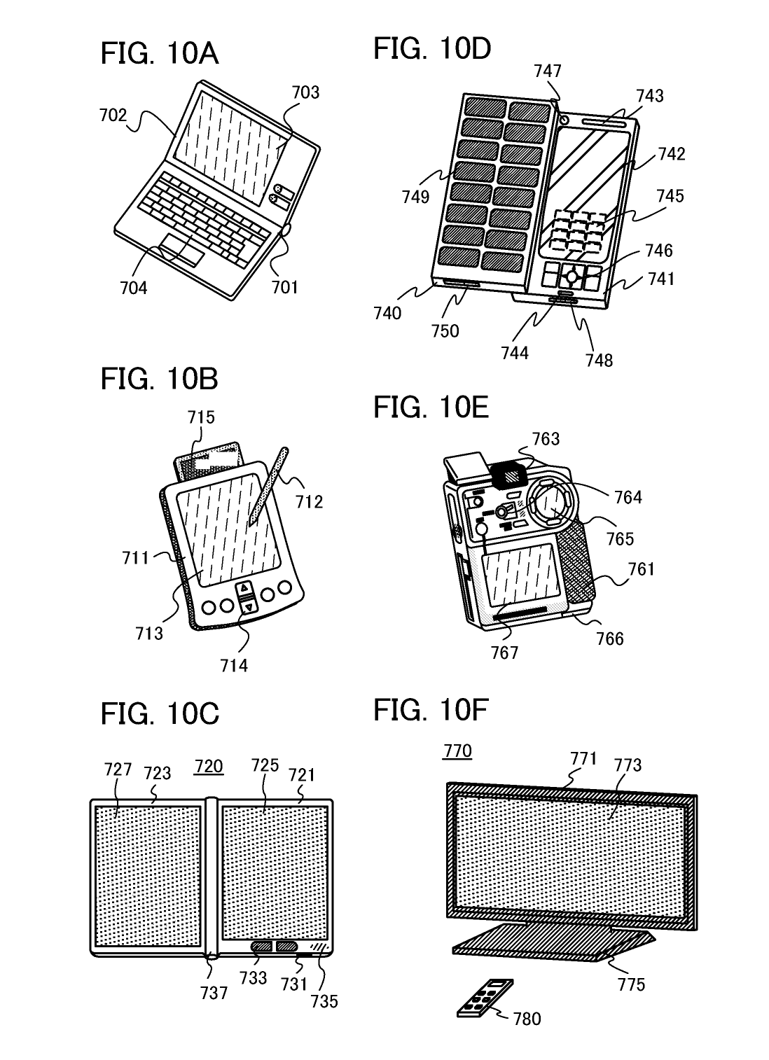

In this embodiment, application of the semiconductor devices described in the above embodiment to electronic devices will be described with reference to FIGS. 10A to 10F. In this embodiment, the cases will be described in which the semiconductor devices described in the above embodiment are applied to electronic devices such as a computer, a mobile phone handset (also referred to as a mobile telephone or a mobile telephone device), a portable information terminal (including a portable game console, an audio player, and the like), a camera such as a digital camera or a digital video camera, an electronic paper, and a television device (also referred to as a television or a television receiver).

FIG. 10A illustrates a laptop personal computer that includes a housing 701, a housing 702, a display portion 703, a keyboard 704, and the like. At least one of the housings 701 and 702 is provided with a memory circuit, and the memory circuit includes the semiconductor device described in Embodiment 3. Therefore, a laptop personal computer in which writing and reading of data are performed at high speed, data can be stored for a long time, and power consumption is sufficiently reduced can be realized.

FIG. 10B illustrates a portable information terminal (personal digital assistant (PDA)). A main body 711 is provided with a display portion 713, an external interface 715, operation buttons 714, and the like. Further, a stylus 712 or the like for operation of the portable information terminal is provided. In the main body 711, the semiconductor device described in Embodiment 3 is provided. Therefore, a portable information terminal in which writing and reading of data are performed at high speed, data can be stored for a long time, and power consumption is sufficiently reduced can be realized.

FIG. 10C illustrates an electronic book 720 including electronic paper. The electronic book 720 includes two housings, a housing 721 and a housing 723. The housing 721 and the housing 723 are provided with a display portion 725 and a display portion 727, respectively. The housings 721 and 723 are combined by a hinge 737 and can be opened or closed with the hinge 737 as an axis. The housing 721 is provided with a power supply 731, an operation key 733, a speaker 735, and the like. At least one of the housings 721 and 723 is provided with a memory circuit, and the memory circuit includes the semiconductor device described in Embodiment 3. Therefore, an electronic book in which writing and reading of data are performed at high speed, data can be stored for a long time, and power consumption is sufficiently reduced can be realized.

FIG. 10D illustrates a mobile phone handset which includes two housings, a housing 740 and a housing 741. Further, the housings 740 and 741 which are developed as illustrated in FIG. 10D can overlap with each other by sliding; thus, the size of the mobile phone handset can be reduced, which makes the mobile phone handset suitable for being carried. The housing 741 includes a display panel 742, a speaker 743, a microphone 744, operation keys 745, a pointing device 746, a camera lens 747, an external connection terminal 748, and the like. The housing 740 includes a solar cell 749 for charging the mobile phone handset, an external memory slot 750, and the like. In addition, an antenna is incorporated in the housing 741. At least one of the housings 740 and 741 is provided with a memory circuit, and the memory circuit includes the semiconductor device described in Embodiment 3. Therefore, a mobile phone handset in which writing and reading of data are performed at high speed, data can be stored for a long time, and power consumption is sufficiently reduced can be realized.

FIG. 10E is a digital camera including a main body 761, a display portion 767, an eyepiece portion 763, an operation switch 764, a display portion 765, a battery 766, and the like. In the main body 761, a memory circuit is provided, and the memory circuit includes the semiconductor device described in Embodiment 3. Therefore, a digital camera in which writing and reading of data are performed at high speed, data can be stored for a long time, and power consumption is sufficiently reduced can be realized.

FIG. 10F is a television set 770 including a housing 771, a display portion 773, a stand 775, and the like. The television set 770 can be operated with an operation switch of the housing 771 or a remote controller 780. A memory circuit is provided in at least one of the housing 771 and the remote controller 780, and the memory circuit includes the semiconductor device described in Embodiment 3. Therefore, a television set in which writing and reading of data are performed at high speed, data can be stored for a long time, and power consumption is sufficiently reduced can be realized.

Thus, the semiconductor devices according to the above embodiment are provided in the electronic devices described in this embodiment. Therefore, power consumption of the electronic devices can be reduced.

### Example 1

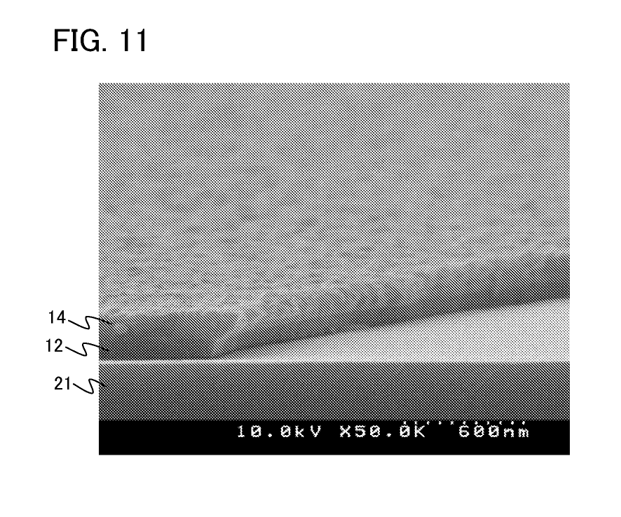

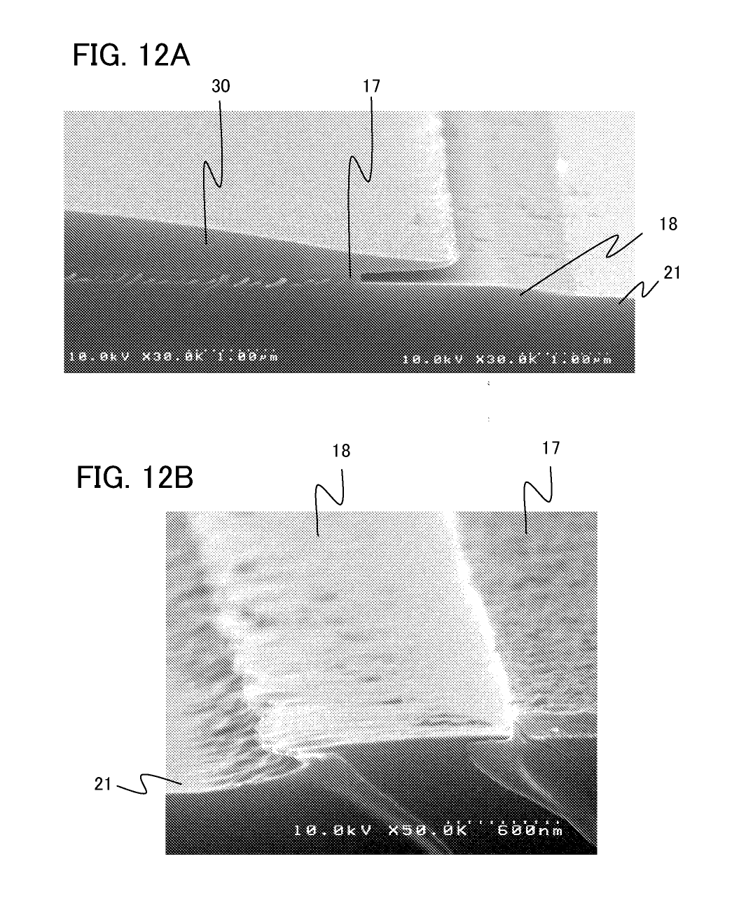

In this example, effects generated by removing or not removing an end of a single crystal semiconductor film provided by a manufacturing method described in Embodiment 1 will be described with reference to FIG. 11, FIGS. 12A and 12B, FIG. 13, and FIG. 14.

A method for manufacturing each of Sample A, Sample B, Sample C, Sample D, and Sample E which were observed in this example will be described below. Since the manufacturing method up to a step of providing a semiconductor film over a base substrate is the same in all the cases of Sample A, Sample B, Sample C, Sample D, and Sample E, the method used in all of the cases will be described at once.

As a semiconductor substrate, a rectangular single crystal silicon substrate with a size of 5 inches per side was used. As the base substrate, a 0.7-mm-thick non-alkali glass substrate (EAGLE XG manufactured by Corning Incorporated) was used.

First, a silicon oxide film (hereinafter referred to as an oxide film) is formed as an insulating film, on a surface of the single crystal silicon substrate. The oxide film was formed on the surface of the single crystal silicon substrate by performing thermal oxidation treatment on the single crystal silicon substrate in an oxidative atmosphere to which chlorine was added. In this example, the thermal oxidation treatment was performed at 950° C. for 210 minutes in an oxidative atmosphere containing hydrogen chloride (HCl) at 3 vol. % with respect to oxygen. Thus, the oxide film with a thickness of 100 nm was formed.

Next, the single crystal silicon substrate was exposed to hydrogen ions through the oxide film with an ion doping apparatus, so that an embrittlement region was formed at a predetermined depth from the surface of the single crystal silicon substrate.

Next, a surface of the oxide film and a surface of the base substrate were disposed so as to face each other and then, the single crystal silicon substrate and the base substrate were bonded to each other with the oxide film interposed therebetween.

Next, thermal treatment was performed so that the single crystal silicon substrate was separated along the embrittlement region; thus, an SOI substrate in which the single crystal silicon film was provided over the glass substrate with the oxide film interposed therebetween was obtained. The heat treatment was performed in a heating furnace at 200° C. for 2 hours and then at 600° C. for 2 hours. The thickness of the single crystal silicon film after the separation was 140 nm.

The SOI substrate formed through the above steps is Sample A.

Then, Sample A was observed with a scanning electron microscope (SEM). FIG. 11 shows a SEM image (magnified by 50000 times) of an end of Sample A. As shown in FIG. 11, in the end of Sample A, the taper angle of an oxide film 12 with respect to a surface of a substrate 21 was approximately 95°, and the angle of a single crystal silicon film 14 with respect to the surface of the substrate 21 was 150°.

Next, an end of the single crystal silicon film and an end of the oxide film, which had been obtained through the above steps, were removed by etching. First, a resist mask was formed over the single crystal silicon film by a photolithography method. The resist mask was formed over the single crystal silicon film but formed so as not to cover the end of the single crystal silicon film because the end would be removed. In this example, the resist mask was formed so that the distance between the periphery of the single crystal silicon film and the periphery of the resist mask was approximately 3 mm.

Next, the etching was performed on part of the single crystal silicon film and part of the oxide film with the use of the resist mask. For the etching, dry etching was performed using a parallel-plate reactive ion etching (RIE) apparatus.

The single crystal silicon film and the oxide film were etched for approximately 180 seconds under the following conditions: the bias power of a parallel plate was 300 W; the pressure in a chamber was 26.66 Pa; a fluorine-based gas was used as an etching gas; and the gas flow rate of SF₆ to He was 20:20 (sccm); thus, the ends of the single crystal silicon film and the oxide film were removed.

The SOI substrate formed through the above steps is Sample B.

Then, Sample B was observed with a scanning electron microscope. FIG. 12A shows a SEM image (magnified by 30000 times) of an end of Sample B. As shown in FIG. 12A, in the end of Sample B, the taper angle of an oxide film 18 with respect to a surface of the substrate 21 is approximately 7°, and the angle of a single crystal silicon film 17 with respect to the surface of the substrate 21 is 90°. Further, over the single crystal silicon film 17, a resist 30 was observed.

Next, the SOI substrate obtained through the above steps is processed with hydrofluoric acid for 200 seconds to remove an oxide film such as a natural oxide film formed on a surface of the single crystal silicon film.

The SOI substrate formed through the above steps is Sample C.

Then, Sample C was observed with a scanning electron microscope. FIG. 12B shows a SEM image (magnified by 50000 times) of an end of Sample C. As shown in FIG. 12B, in Sample C in which part of the single crystal silicon film 17 and part of the oxide film 18 are removed, it was observed that neither part of the single crystal silicon film 17 nor part of the oxide film 18 peeled off the substrate 21.

When the taper angle of the oxide film with respect to a surface of the substrate is approximately 7° and the angle of the single crystal silicon film with respect to the surface of the substrate is 90° as in Sample B, it is possible to suppress side etching due to a difference between the etching rate of the oxide film and the etching rate of the glass substrate in a cleaning step; thus, removal of part of the glass substrate between the oxide film and the glass substrate can be suppressed. It is considered that this permitted prevention of peeling of part or the whole of the single crystal silicon film from the base substrate.

Next, as a comparative example of Sample C, Sample D was prepared. Sample D was obtained in such a manner that after an SOI substrate was formed similarly to Sample A, the SOI substrate was processed with hydrofluoric acid for 200 seconds while ends of a single crystal silicon film and an oxide film were not removed, so that an oxide film such as a natural oxide film formed on the single crystal silicon film was removed.

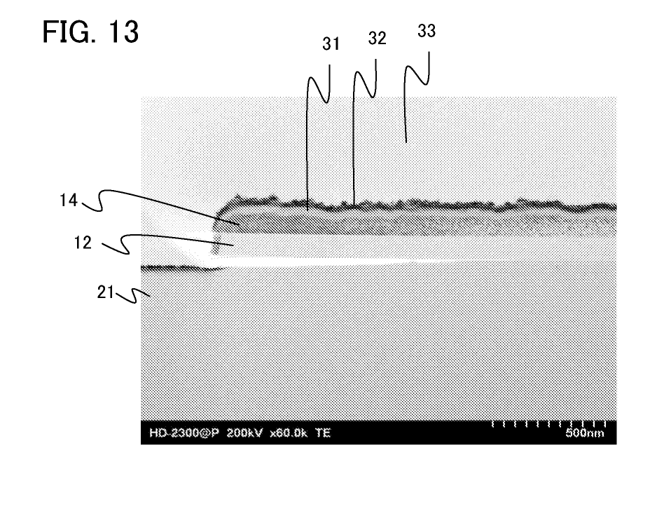

Then, Sample D was observed with a scanning transmission electron microscope (STEM). FIG. 13 shows a STEM image (magnified by 60000 times) of an end of Sample D. As shown in FIG. 13, around the periphery of the single crystal silicon film 14, it was observed that part of the single crystal silicon film 14 and part of the oxide film 12 peeled off the substrate 21. Note that a carbon deposition film 31, a platinum coat 32, and an FIB protective film 33 which were over the single crystal silicon film 14 were formed for observation with STEM, so they are not included in Sample D.

In Sample D, the taper angle of the oxide film 12 with respect to a surface of the substrate 21 is 95° and the angle of the single crystal silicon film 14 with respect to the surface of the substrate 21 is 150°; thus, part of the glass substrate was removed at the interface between the oxide film 12 and the substrate 21 due to a difference between the etching rate of the oxide film and the etching rate of the glass substrate in a cleaning step. It is considered that this caused part of the single crystal silicon film 14 to peel off the substrate 21.

Next, in order to evaluate adhesion between the oxide film and the glass substrate in Sample C, a tape test was conducted. In the tape test, a polyimide tape was attached to the ends of the single crystal silicon film and the oxide film, the portion to which the polyimide tape was attached was rubbed strongly with a finger, and then the tape was peeled slowly. Before and after the tape test, whether the part of the single crystal silicon film and the part of the oxide film peeled was observed with an optical microscope.

In Sample C magnified by 1000 times with an optical microscope, peeling was not observed. On the other hand, in the case where the ends were not removed, peeling in the range of several tens of micrometers to several hundred micrometers was observed with the optical microscope when the tape test was conducted by the above method.

The comparison between Sample C in FIG. 12B and Sample D in FIG. 13 reveals that it is possible to suppress peeling of the single crystal silicon film and the oxide film around an end of the single crystal silicon film when part of the single crystal silicon film and part of the oxide film are removed.

Next, Sample E was obtained in such a manner that a sample formed similarly to Sample B was processed with hydrofluoric acid and then was irradiated with laser light to be planarized, and was observed with STEM.

Specifically, Sample B was processed with hydrofluoric acid for 155 seconds, so that an oxide film such as a natural oxide film formed on a surface of the single crystal silicon film was removed. After that, the single crystal silicon film was irradiated with laser light. Sample E was formed by irradiation with approximately 20 shots of XeCl laser light (λ=308 nm) as the laser light under the following conditions: the repetition rate was 30 Hz and the scanning speed was 0.5 mm/sec.

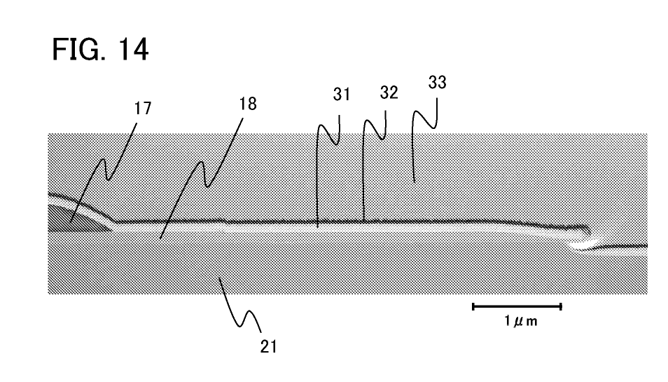

FIG. 14 shows a STEM image of Sample E. It was observed that the periphery of the single crystal silicon film 17 was on the inner side than the periphery of the oxide film 18 by approximately 4 μm to 5 μm. In addition, it was observed that there was a gap between the oxide film 18 and the substrate 21 due to treatment with hydrofluoric acid. However, neither a crack from the gap nor peeling of the oxide film 18 and the single crystal silicon film 17 were observed. Note that the carbon deposition film 31, the platinum coat 32, and the FIB protective film 33 which were over the single crystal silicon film 17 were formed for observation with STEM, so they are not included in Sample E.

Sample E shows that even when laser light irradiation is performed for planarization after treatment with hydrofluoric acid, it is possible to suppress peeling of the single crystal silicon film and the oxide film around an end of the single crystal silicon film.

### Example 2

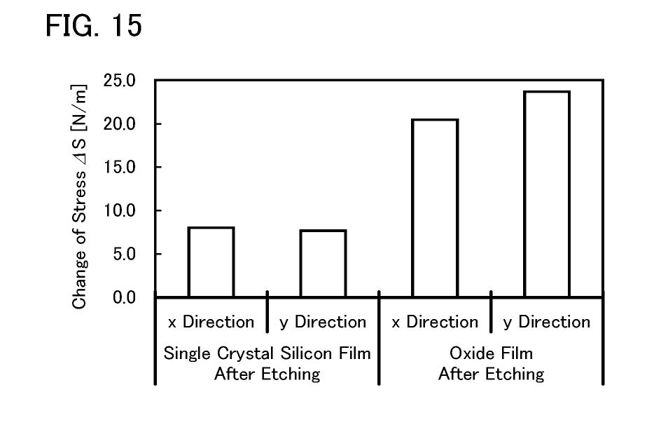

In this example, measurement results of stresses of a single crystal silicon film and an oxide film in an SOI substrate manufactured in a manner similar to that of Sample A in Example 1 will be described with reference to FIG. 15.

First, the SOI substrate was formed in a manner similar to that of Sample A in Example 1.

Next, the films in the SOI substrate was removed one by one by etching, and the amounts of curling of the SOI substrate after the etching were measured. From the measurement results, change in stress due to the film removed by etching was calculated. The measurement was performed using Tencor FLX-2320 thin film stress measurement system in the direction in which the films were formed and in the direction perpendicular to the above direction.

Specifically, the single crystal silicon film in the SOI substrate was removed by etching and then, change in stress after the etching was calculated. After that, the oxide film was removed by etching and change in stress after the etching was calculated. FIG. 15 shows the results. The vertical axis represents change in stress. The positive sign of the vertical axis indicates an increase of tensile stress.

As shown in FIG. 15, tensile stress was increased after removal of the single crystal silicon film and after removal of the oxide film. These results reveal that compressive stress occurred in both the single crystal silicon film and the oxide film.

Further, the amount of change in stress after the etching of the single crystal silicon film was greater than the amount of change in stress after the etching of the oxide film. This indicates that the compressive stress of the single crystal silicon film was higher than that of the oxide film. It is suggested that, due to such a difference in compressive stress, part of a single crystal silicon film and part of an oxide film peel off a glass substrate when neither part of the single crystal silicon film nor part of the oxide film is removed as in the case of Sample D in Example 1. In addition, it is also suggested that, when part of a single crystal silicon film and part of an oxide film are removed as in the cases of Sample C and Sample E in Example 1, there is not a difference in stress, resulting in prevention of peeling.

This application is based on Japanese Patent Application Serial No. 2011-033698 filed with the Japan Patent Office on Feb. 18, 2011, the entire contents of which are hereby incorporated by reference.

What is claimed is:

1. A method for manufacturing an SOI substrate comprising a semiconductor film over a base substrate with an insulating film interposed therebetween, wherein the semiconductor film is provided on the insulating film over the base substrate, the method comprising the step of:
removing part of the semiconductor film and part of the insulating film so that each of a periphery of the semiconductor film and a periphery of the insulating film is tapered and the periphery of the semiconductor film is on an inner side than the periphery of the insulating film.

2. The method for manufacturing an SOI substrate, according to claim 1, further comprising the step of:
forming a resist mask over the semiconductor film so that the part of the semiconductor film is exposed, wherein the resist mask has a tapered shape,
wherein the part of the semiconductor film and the part of the insulating film are removed using the resist mask.

3. The method for manufacturing an SOI substrate, according to claim 1, wherein the part of the semiconductor film is removed so that the semiconductor film has a taper angle in a range from 30° to 90°.

4. The method for manufacturing an SOI substrate, according to claim 1, wherein the part of the insulating film is removed so that the insulating film has a taper angle in a range from 3° to 60°.

5. The method for manufacturing an SOI substrate, according to claim 1, wherein the part of the semiconductor film and the part of the insulating film are removed so that a distance between the periphery of the semiconductor film and the periphery of the insulating film is less than or equal to 50 mm.

6. The method for manufacturing an SOI substrate, according to claim 1, wherein the part of the semiconductor film and the part of the insulating film are removed using an atmospheric pressure plasma etching apparatus.

7. The method for manufacturing an SOI substrate, according to claim 1, wherein the insulating film is an oxide film.

8. The method for manufacturing an SOI substrate, according to claim 1, wherein the base substrate is a glass substrate.

9. A method for manufacturing an SOI substrate, the method comprising the steps of:
forming an insulating film on a semiconductor substrate;
forming an embrittlement region in the semiconductor substrate;
attaching the semiconductor substrate to a base substrate with the insulating film interposed therebetween;
forming a semiconductor film over the base substrate with the insulating film interposed therebetween by separating the semiconductor substrate along the embrittlement region; and
removing part of the semiconductor film and part of the insulating film so that each of a periphery of the semiconductor film and a periphery of the insulating film is tapered and the periphery of the semiconductor film is on an inner side than the periphery of the insulating film.

10. The method for manufacturing an SOI substrate, according to claim 9, further comprising the step of:
forming a resist mask over the semiconductor film so that the part of the semiconductor film is exposed, wherein the resist mask has a tapered shape,
wherein the part of the semiconductor film and the part of the insulating film are removed using the resist mask.

11. The method for manufacturing an SOI substrate, according to claim 9, wherein the part of the semiconductor film is removed so that the semiconductor film has a taper angle in a range from 30° to 90°.

12. The method for manufacturing an SOI substrate, according to claim 9, wherein the part of the insulating film is removed so that the insulating film has a taper angle in a range from 3° to 60°.

13. The method for manufacturing an SOI substrate, according to claim 9, wherein the part of the semiconductor film and the part of the insulating film are removed so that a distance between the periphery of the semiconductor film and the periphery of the insulating film is less than or equal to 50 mm.

14. The method for manufacturing an SOI substrate, according to claim 9, wherein the part of the semiconductor film and the part of the insulating film are removed using an atmospheric pressure plasma etching apparatus.

15. The method for manufacturing an SOI substrate, according to claim 9, wherein the insulating film is an oxide film.

16. The method for manufacturing an SOI substrate, according to claim 9, wherein the base substrate is a glass substrate.

17. An SOI substrate comprising:
a base substrate;
an insulating film on the base substrate; and
a semiconductor film on the insulating film,
wherein the insulating film and the semiconductor film each have compressive stress,
wherein the compressive stress of the insulating film is higher than that of the semiconductor film, and
wherein a periphery of the semiconductor film is on an inner side than a periphery of the insulating film.

18. The SOI substrate according to claim 17,
wherein a taper angle of the periphery of the insulating film is larger than or equal to 3° and smaller than or equal to 60°.

19. The SOI substrate according to claim 17,
wherein a taper angle of the periphery of the semiconductor film is larger than or equal to 30° and smaller than or equal to 90°.
